(19) United States
(12) Patent Application Publication
(10) Pub. No.: US 2015/0327406 A1
(43) Pub. Date: Nov. 12, 2015

(54) DEVICE FOR PASSIVE COOLING OF ELECTRONIC EQUIPMENT AND POWER SUPPLY FOR A COLLECTION OF A PLURALITY OF COMPUTER UNITS

(71) Applicant: Fjord IT AS, Oslo (NO)

(72) Inventor: Helge GALLEFOSS, Oslo (NO)

(73) Assignee: Fjord IT AS, Oslo (NO)

(21) Appl. No.: 14/648,981

(22) PCT Filed: Dec. 3, 2013
(86) PCT No.: PCT/EP2013/075368

§ 371 Date: Jun. 2, 2015

(30) Foreign Application Priority Data
Dec. 3, 2012 (NO) 20121452

(51) Int. Cl. H05K 7/20

(52) U.S. Cl. CPC H05K 7/20709

(57) ABSTRACT

Device for cooling electronic equipment, comprising a supply channel (A, 6) for cold air and an outlet channel (D, 9), at an inlet side and an outlet side (C) of the electronic equipment (2, 3), respectively, The circulation is largely being provided by a chimney effect. The electronic equipment (2, 3) is adapted to let air flow vertically through the equipment (2, 3). There are openings provided to let a part of the air that has been heated, re-enter at the underside of the electronic equipment. The invention also relates to a power supply to a collection of computer units, comprising a high voltage power supply coupled to a transformer having a low voltage output. The low voltage output is coupled to a plurality of electrical accumulators, which are coupled to the computers, for supplying the computers with electrical low voltage power.

The present invention relates to a new topology, system architecture and power distribution combined with a method for passive cooling of electronic equipment that releases heat and which has a need for cooling, such as for example, computers and associated equipment placed in a rack.

Electronic equipment, for instance computers, generates significant amounts of heat when it is in use. If this heat is not transported out it can lead to an overheating or damaging of the equipment. In the worst case this can lead to fires. In large assemblies of computer equipment there are problems with removing this heat. Therefore, the equipment is often placed in a room with a cooling aggregate. In this case a completely closed and airtight environment is created and active components are used to remove the heat that is generated in the computer equipment, from the room with air conditioning, heat pumps or chilled water. All these solutions, which to a large extent are not very energy efficient, require a supply of energy. Such traditional cooling of a computer room often consumes equal amount of power, or more, than the power consumption of the computer equipment itself.

The second energy-consuming challenge is that all equipment are contained in separate enclosures with separate power supplies causing unnecessary airflow obstacles and duplicates of power supply units which are a resource that could be shared between the different operational equipment if a total system setup was planned from the beginning.

The third energy challenge is that all the equipment in the individual enclosures are mounted in such a way that airflow is forced into narrow horizontal streams which causes more resistance than if the heated air could flow vertically and naturally by thermal effects.

The fourth challenge is that the power distribution itself is extremely complex and that the energy—supplied to the systems has been converted from AC to DC to AC to DC numerous times at different voltages. This creates a huge waste of energy and materials as well as adding potential risk of failure from the huge number of components, interconnects points and complex system designs.

The reason behind these energy-demanding designs is that products of today that are used for cooling of the electronic equipment are designed as standalone products—to be sold separately and installed at location and connected together. But today, new software and technology developed—called virtualization—disconnects the physical hardware with what is defined as a “server”. Now it is possible to make a pool of hardware resources, create an abstraction layer between the hardware, and create virtual servers with the resources as a shared hardware resource pool. Without significant performance penalties, it is also possible to share these resources in a much more efficient way than the traditional physical server space. If powered by gas. Gartner claims that virtualizing one physical server saved 4 tons of CO2 emissions per year.

This technology is also referred to as laaS—Infrastructure as a Service, and it implies that service providers can connect these physical hardware resources and create data center hosting environments on different physical locations, but operationally they appear as being one hosting environment in terms logical appearance and performance. This has created a new term in the business called VDC—Virtual Data Center. This virtual datacenter can totally replace a physical data center with physical servers in all functions. This also means that access to these resources is not anymore related to buying or renting physical infrastructure—physical products manually mounted and connected in the datacenter—this can now all be virtualized.

This is a paradigm shift and opens for a new way of constructing and put together the hardware resources behind the new laaS product offerings. This invention is about moving out of the product/box regime and move into a new architecture that is looking at the whole production and value chain and connect and mount the hardware in a more energy efficient and eco-friendly way—also considering the Life Cycle of all materials involved.

This new system architecture has 5 basic elements:
1. Operational hardware is removed from enclosures and mounted in one huge expandable rack/rail structure—with connectors and plugin modules accessible from top or side.
2. These heat producing cards/modules are mounted vertical in this new data center infrastructure whereas the cold air is coming from under the electronic equipment and flows naturally in vertical direction upwards as the cold inlet air is getting heated by the components in operations. This will reduce airflow resistance and cause less power consumptions from the fans on the boards.
3. From the power inlet to the data center, the AC (Alternating Current) is once converted to DC (Direct Current).
4. The power distribution to the active boards and modules is designed to be a redundant shared resource for the whole system—significantly reducing the number of power supplies—thus also creating fewer components and potentially failing units. The power distribution to the active components is a combination of regular power supply (for each component) and a UPS service (Uninterruptable Power Supply) for the whole setup.
5. The system follows patent application NO20111401 for free cooling and uses thermal effects with a controlled feedback loop of airflow to adjust inlet system air to preferred temperature.

The invention represents a new radical way of constructing data processing environments and is not limited to laaS—but could also be used for super computers and hybrid hosting environments.

The benefits of the invention are to significantly reduce power consumption as well as the use of hardware/material resources (enclosures, metals, cabling, paint, power supplies and hardware components). This approach will have significant value in terms of reducing use and cost of materials. The whole approach is addressing the challenge of product lifecycle and how we build systems to reduce energy and material costs to save unnecessary challenges to climate and nature.

The general approach of this invention is to create an energy efficient framework and layout/organization of core computer components to be mounted and interfaced in a more efficient way. This approach will open for using best practice industry standard solutions on data processing, backplane communications, storage and networking. It does not challenge any individual solutions on core data production/processing, services and networking, but it does challenge how we mount and interconnect these components, as well as how we package these products and how we cool them. It also a challenge how we relate to “products” as physical entities and it moves the focus to the real operational functions and services that this business is offering to the market—which now are becoming virtual.

The invention is primarily meant for a mechanical installation in a room for hosting computers—a server farm. In a preferred embodiment it comprises two main zones, one cold and one warm zone divided in a horizontal way that the downward side of the racks is the cold zone and the upward side is the hot zone, this is also known in the business as hot aisle/cold aisle systems, but in this invention it is angled 90 degrees. In a way, it is possible to say that the racks are “lying” on the floor with the front-side down. And the “racks” are not really traditional 19″ racks but more like enclosures that are not limited in height for all active components.

The present invention is not limited to “standard rack sizing”. The standard rack width 19″ could and should be followed initially to be able to use standard sized equipment, but this is not a restriction. The maximum height of a 19″ rack is normally around 2 meters. The “racks” are lying horizontally, the maximum length is not limited by the height of the room or standards, the rack could be as long or short as practical to the group of components that you would want to bundle together in a system. It also means that backplane communication channels for the components could be extended to any physical length, just limited by standards and system bandwidth limitations—and most certainly—not “in box” limitations.

This architecture opens for completely new methods of connecting standard industry technology in a radical way with less use of materials, less energy use and higher redundancy related to fewer components and failure possibilities—at the same time offering N+N redundancy topology for the individual system components. In general, the whole system design is about resourcing a pool of hardware components in an energy efficient setup to ensure redundancy, failover mechanisms with a minimum use of energy, active and passive components.

For the invention to function optimally with free air-cooling only, it is an advantage to have sufficient supply of air below 30 degrees and a chimney through which the used and heated air can rise, either to free air or as input to a system that can harness the benefit of heated air either directly or with heat exchangers.

The Green Grid (http://thegreengrid.com)—resent studies (EMEA meeting in Brussels 20/21.12.2012) concluded that free air cooling will be very important for energy efficiency the next years and that the standards of what is acceptable data center climate from the US organization ASHRAE are really conservative and that temperatures above 10 degrees, and even a lower limit, may actually be beneficial as hardware failure is reduced to almost 50% for operations temperature at 15 degrees compared to 28 degrees whereas an increase from 28 to 35 will only give just slightly higher risk of hardware failure. The Norwegian climate year around is by these conclusions very advantageous for hosting data with a free air-cooling solution. The hardware needs stable temperature, and the free air-cooling system described in patent application NO20111401 secures these stable temperatures.

This invention uses the same thermal principles, but the airflow is within this concept a vertical system and follows the basic physical principles of thermal flow, thereby reducing the energy used to move air as it lets heated air rise vertical inside the system.

This setup is general, but in this system according to the present invention it is exemplified by a closed container based system, however the system is generic and could be applied to any setting where free or cooled cold air is available. In this explanation of system solution we use a 20 ft. container with a raised floor. Free air is coming in to the container at below “floor” level (min 40 cm) from both ends. If necessary (based on local air quality)—the air is filtered with high volume low resistance particle filters at all air entries. Below floor level is cold supply zone A. Inlet zone B is the mixed air zone for air input to the hardware. This zone is a mix between air coming from supply channel or lower level zone A and the air heated by the hardware coming from an outlet side or zone C due to a slightly higher air pressure in this zone. A portion of the heated air flows from the outlet zone C through an outlet channel D. The damper between the outlet zone C and outlet channel D controls the air pressure in the inlet zone B. This pressure creates a mixture between cold free air and heated air and secures a steady input temperature to the hardware.

The cross section view shows the general airflow in the system exemplified as a 20 ft. container, but could be used in any configuration with a floor based system with cold air flowing without any significant resistance in this lower level zone A and enabling this cold air to stream into the areas below the “racks” into the inlet zone B zone in the system setup. A diffusor system between outlet zone C and inlet zone B will mix the cold air with the heated air pushed down to floor level by the slightly higher pressure in the outlet zone C. This diffusor could be just a vented floor that transfer some of the heated air down to inlet zone B, alternatively, the laying racks has a e.g. 5-10 cm opening between floor level and sides. Dependent on heat development and air volumes, and possibly different cooling needs (different temperatures in different sections of the rack) vents, either automatically or manually, will enable the correct flow control, and ensure that different airflows to the different sections caused by different energy or cooling needs can be adaptive.

The inlet zone B and outlet zone C should be organized in segmented areas to limit potential fire spread situations, like making “closed fire-cells”. In general fire hazard in these environments are low as most materials do not burn easily, but high density of power can create situations that might cause local fire, but the chance of spread is very low. As patent application NO20111401 describes that the fire protection can be done with high-pressure water atomizers in inlet zone B and further vertical segmentation of production areas will make a very secure production environment in terms of both physical access and fire.

The invention represents a new way of organizing the complete data center system components and how to interconnect and power these units. As the data center today is build as a kind of building block system with individual components, all of them are self powered and constructed to be “stand alone” systems. This means that all functional components are embedded in standard sized enclosures with power supplies, most often redundant (2 or more).

All these power supplies are provided with 230/110 AC converting the current into usable 12V DC (now being more and more standard for all boards). As the working voltage for most components in the data center is 12V, it does not make sense to have a separate 110/230 to 12V power supply for each working system, it creates a huge excess of components as well as an increased number of component failure possibilities. The power efficiency of a more centralized power distribution architecture has the possibility of higher power efficiency.

The excess of materials use by packing each component into a separate enclosure with separate power supplies represent a huge area of materials savings. This will have a significant value in respect to the financial and ecological life Cycle Costs of the products as building blocks, providing the services from the data center.

Removing the enclosures and centralizing the power supplies and distribution and only convert from AC to DC once, will significantly reduce use of power and materials.

The invention's proposed architecture is a specific exemplification of generic general system architecture. There are today established a rich set of industry standards on physical sizes, connectors, electrical system voltage, protocols, system buses etc. Even though it would be advantageous to create a new set of standards, this is not practical so this system design is done both to accommodate established standards as well as opening for new ways of interconnecting and powering system devices. In general, there are a lot of industry standard components that enables flexible interconnect of system buses, and there are a lot of components for building card rail systems and bus connections. This world of connectors and devices enable this invention to adapt almost any standard server, storage, networking and power supply device to interconnect with some flexibility.

The system also accommodate traditional 19″ box enclosures except for the mount of these enclosures will be from “behind”—which means that special “rack ears” has to be mounted at the backside as well, not at the front-side as is industry standard. If not possible to service the unit from the backside, servicing from the front side (in this setup downside), can also be done, but then servicing the unit will be a bit more awkward. Still there will be an accessible service area both from above and below.

The invention can be used in hybrid mode; vertical mount of standard products to give better cooling, but operating on 230V AC. The system can instantly be used for anyone who wants to put systems together based on standard OEM boards and solutions. Hybrid solutions must be expected in order to set up a complete data center infrastructure service.

The general approach to mount and connect standard system cards and devices would be to follow these standard components mounting and configuring as much as possible, meaning horizontal cards installs are turned 90 or 180 degrees with either system bus connectors sitting either horizontal in rack or vertical on system backplane.

### System Components and Cabling Structure

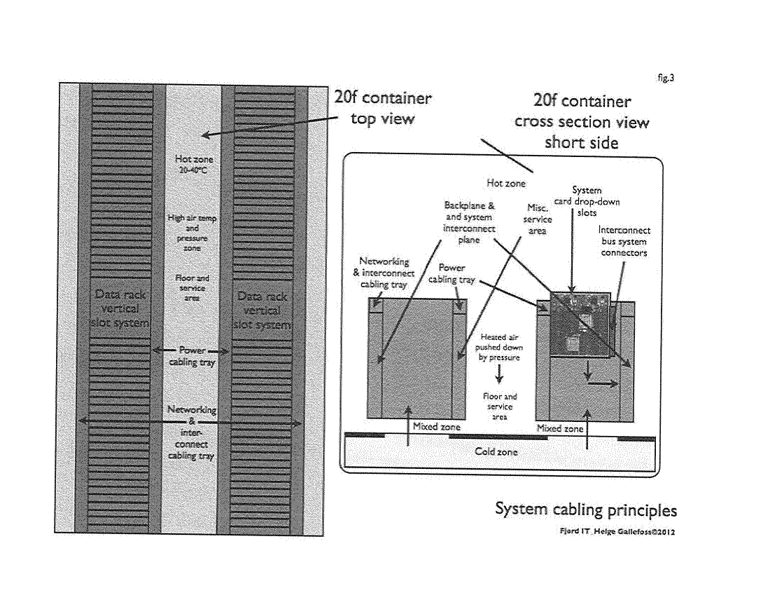

The cabling and system setup is described in FIG. 3.

There are two trays in each row of racks. The rows are mirrored to each other. Closest to pathway/working area is the power trays. These trays are used for the low voltage DC power cabling, and the Misc, service area will be used for high voltage AC PDUs (Power Distribution Units). Both areas will have lids to easily be opened for services, but shall be closed for any normal operations to avoid potential physical “accidents” when service people walk by.

The networking tray works the same way and will contain the fiber- and copper 25 cabling for interconnecting the systems.

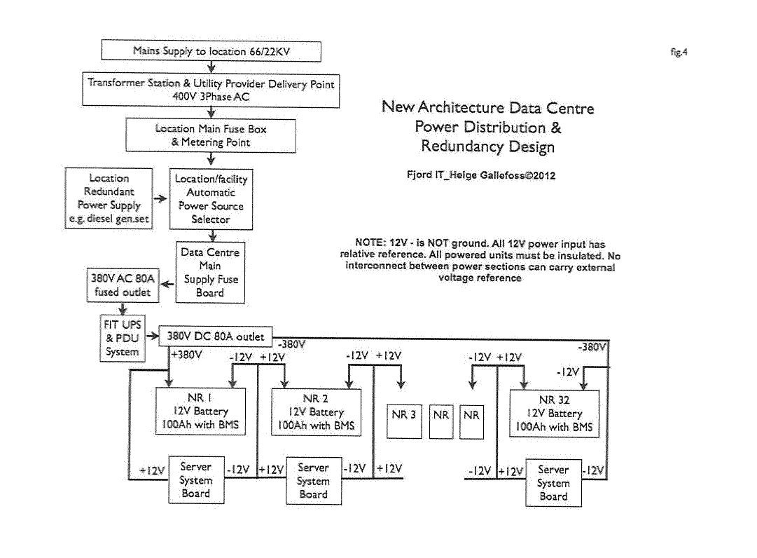

The system architecture proposes a new and very simplified power distribution system. See FIG. 4. The traditional data center power distribution setup as well as the individual product configurations relate only to the “individual product regime”—meaning all products/units have their own AC input with redundant (N+1+?) separate power supply units—creating a huge number of excess components as well as failure points.

All data centers are built with power redundancy and have UPS systems (Uninterruptable Power Supplies). The standard designs of these units is AC to DC conversions, a battery pack of 12V batteries in series and parallel to keep provided system high voltage and current and a DC/AC conversion system and system logic, battery management, failover mechanisms etc. These systems create a “power buffering” service for the data center keeping power to the systems up until a failover power generation system is in full operation and synchronized to the AC pulse on location. Generator backup is normally set to 3 s start-up and will perform power takeover within 7 s. Max capacity of UPS is often 3-8 minutes of operations. These services perform alternative AC high voltage power supply in case of failure situations in the mains. Recently there have been some new designs in the market that drop the DC to AC conversion from UPS and distribute DC 230/380V directly to racks and the equipment having power supplies adapted to DC input. These designs claim to have achieved 15% energy savings. Some others have done DC distribution with 48V and have adjusted the power supplies to use 48V DC input.

This invention outlines another, much more simplified power distribution architecture within the data center. As the UPS systems already are built with 12V batteries, this design provides 12V supply from “these” batteries directly to the operations systems boards as they operate on 12V anyway. By this, the inventions will bypass DC to AC, central fuse boards, local circuits, local PDUs, local PSU (Power Supply Units) and goes directly with just 1-fuse directly to the operational system boards. This approach will immensely simplify use of components, cabling, connections, printed circuits, connection points, transformations and current and voltage conversions—offering an energy savings most likely 20% PLUS.

To visualize this concept, you could say that the batteries in the UPS is not densely packed in a cabinet, but connected in series and or parallel (as they are now) and lined up along the laying racks and individually providing 12V power to the boards mounted along this line of batteries. This is a general approach and board power input could have A and B power source for redundancy. There are now a lot of high quality high capacity standard battery solutions in the market, not only for UPS systems that can handle battery failures, but there are also a pretty advanced battery/power market in the EV industry that can be used with some adaption for this new architecture to ensure redundancy, high availability with less use of materials. Each battery has a BMS (battery management system) that ensure correct load and charge as well as failover if the battery itself either short circuits or drop the line (which would break the whole chain if mounted in series). Another option for energy storage is super-capacitors which have longer life expectancy and much higher charge/discharge cycles capacity.

This is a radical new design, and special care must be taken in wiring and interconnects. If mounted in parallel and batteries and boards are fused, the system can have −12V as ground. This will require short transport of power and the interconnect bus should handle very high amperage (1.000 A+) for each segment. The 230/400V AC will directly charge 12V with a high efficiency high capacity rectifier system. If the load is even in the segments, the setup can be serialized and charged from the ends of the series directly. If so, −12V cannot be connected to common system ground, nor should −12V be used as common ground on interconnected boards. If boards need to be interconnected with common ground. DC/DC converters should be used to galvanic isolate primary and secondary power sides. Fiber wiring only on networking and interconnects could eliminate these obstacles. With these precautions, interconnects should be working. If this is limiting standard equipment to a large extend, DC/DC converters with galvanic separation should be used to isolate potential ground reference issues. These will cause some energy loss, but will still deliver much higher efficiency than current solutions.

The battery/power source arrays could be mounted in the cold zone A below the racks, in the maintenance trays or inside, downside the racks. The batteries/power source arrays should have short wiring to avoid cable loss caused distance.

The system design is flexible, and the power distribution can initially be done traditional or it could be sections with both solutions. It is expected that initially, all units will be connected via the power and cabling trays, and the backplane and systems interconnect is for future use when systems are built by components only. This plane represents a huge advantage in terms of use of materials and life cycle aspects. This plane may also be expanded or replaced by horizontal connectors and the figure must be seen as an example of architecture.

The invention shall now be explained in more detail with reference to the enclosed figures, wherein:

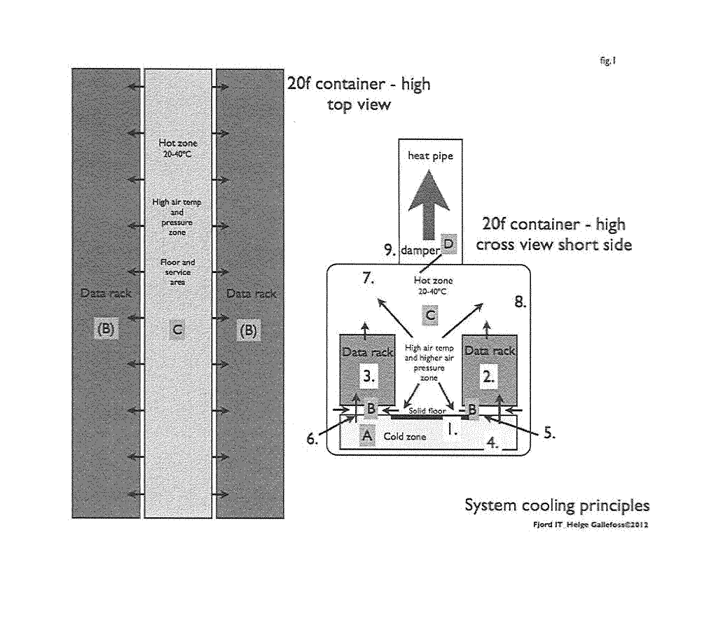

FIG. 1 shows an example of a system solution according to the invention seen from a top view and a cross section view seen from the short side.

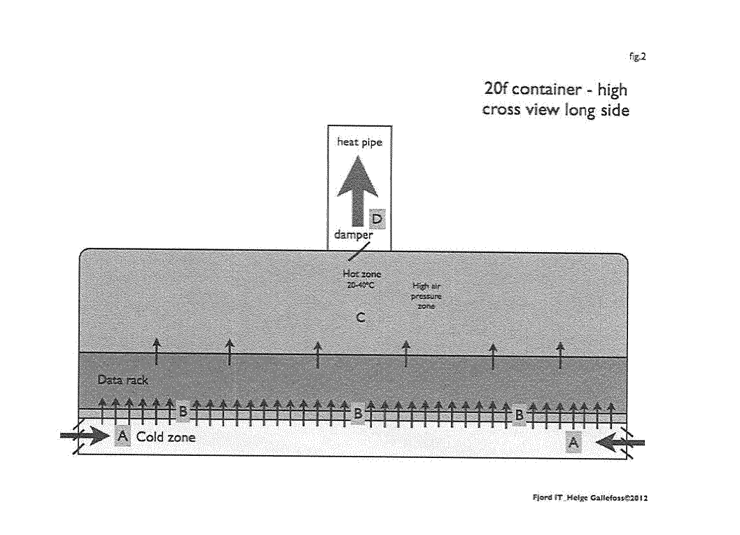

FIG. 2 shows the system solution according to the invention seen from the long side

FIG. 3 shows a generic system-cabling layout.

FIG. 4 shows a electrical power supply diagram for a plurality of computer units.

Reference is first made to FIG. 1. In a preferred embodiment of the invention a room is established which is divided horizontally into two, where the lower part is functioning as a cold zone A. The dividing of the room is carried out by a floor 1 on which electronic equipment, such as computer racks 2, 3 shall stand. The floor 1 can, if necessary, be fitted on a load-bearing construction of pillars (not shown) and the floor 1 ought to be a certain height above a ground base 4 so that large volumes of supplied air can be moved without much resistance or that a noticeable overpressure is created.

The computer racks 2, 3 are fitted on the floor 1 in a line, for example, in two rows that are facing each other, as shown. Under these rows, the floor 1 has an open grid 5 and 6 down towards the cold zone. At the top of the rows there is a ceiling 7 and walls 8 that contains the space around the computer racks 2, 3 as a hot outlet zone C. An outlet channel D for the air outlet from the system is above this roof 7. Hot air rises freely from the hot zone C and at least a part of the heated air can be transported through the outlet channel D to open air. The heated air could also be returned to the inlet zone B and recycled.

A damper 9 between outlet zone C and outlet channel D regulates how much heated air can flow into the outlet channel D. This creates a slightly higher air pressure in outlet zone C that pushes heated air down to the floor level 1 an let heated air from the outlet zone C be mixed with the cold air from inlet zone A. During operation outside air up to 35° C., will flow into the cold zone A. Here, the air is, if necessary, supplied with atomized moisture from fresh water if moisture level is very low or if there are fire situations in some of the units. In general, moisture level is not critical, at least not high moisture level, as all operational equipment will have higher temperature than incoming air, and condensation cannot happen. Very low humidity can cause hazards of electrostatic problems.

The air from the supply channel A and the outlet zone C are mixed and enters the input of the system components in the inlet zone B, the temperature is adjusted to secure a steady input temperature to the systems. Recent conclusions from the Green Grid Association show that the hardware failure has almost 50 of a chance to occur at 15 degrees C. input temperature than 28 degrees. System temperature mix could then be set at 15 degrees to statistically reduce the chances of failure, Air with higher temperatures from inlet zone A, the free air are allowed to flow through the system without any mix, just using the system to balance a mix in such a way that a temperature increase takes some time to let the hardware components adapt to new temperatures over time.

The whole system is controlled by a microcontroller that monitors all the temperature zones and is automatically adjusting the damper 9 to balance the higher air pressure in outlet zone C. This means that in order to have a very controlled temperature increase, the system is programmed to always monitor input temperature in supply channel A and create a input temperature in inlet zone B to ensure a buffer for temperature increase in case of sudden higher outside temperature change to give the hardware the necessary time to physically slowly adapt to the increased air flow temperature over the system boards.

Thus, the system is a complete thermodynamic system with two main zones A and C, and four different temperature and pressure zones A, B, C and D. Air in the main system will move due to different driving sources;
1—The internal fan system of the computers that pulls air from the mixing inlet zone B to the heated air outlet zone C.
2—The chimney effect in the hot zone which makes the heated air rise and thereby also contributes to pull air through the system.
3—The damper (9) that controls how much air can flow from outlet zone C to outlet channel D.

On its way through the computers the air is heated up and expands. The fans that are a conventional part of the computers move the expanded and hot air into the outlet zone C. At the top of this outlet zone C, a variable damper (9) or other through-flow regulator can be arranged, which regulates the pressure in the outlet, zone C so that the hot air is forced down floor level (1) below the computer rack 2, 3 and in to inlet zone B for mixing and then up through the boards into outlet zone C.

Regulated hot air flows from the top of the outlet zone C and into the outlet channel D. The heated air rises past the damper 9 and up the channel/shaft above the damper as the chimney effect ensures that there is a draught in the system. Heated air rises and the thermal effect will contribute to the air flow through the system.

The present invention also makes it possible to perform an efficient and direct extinguishing of small fires in the computer racks. A nozzle 15 can be arranged in the inlet zone B. This nozzle 15 is capable of spraying in atomized water to bring the air humidity up to 100%. This saturated air is then led into the system board and components. Such saturated air will effectively cool the build-up of fires and ensure that the fire does not spread further. A temperature sensor in each computer board monitors the temperature and if the temperature in any given computer rack exceeds a pre-set temperature, the nozzle below connected to the computer rack will start to spray in atomized water. At the same time, the flow to the actual computer rack will preferably be closed to prevent any shorting. A smoke/fire detection/alarm for one rack will immediately shut down the power to this rack.

Even if the invention above is described as a completely passive system for air-cooling, where the fans in the computers are the only active means that are used to make the air circulate, it is, of course, also possible to use fans elsewhere, either periodically or permanently, to help the circulation of air. It is also possible to cool the supplied air, at least periodically, if the temperature is not sufficiently low. However, what is important is that the cooling system, in the main, is a passive system with minimal need for additional cooling.

1. A system for cooling of electronic equipment that releases heat and has a need for cooling, the system comprising a supply channel for cold air to the inlet zone, situated at the underside of the electronic equipment, and an outlet channel from an outlet zone situated at the upper side of the electronic equipment, for transporting air that has been heated up by the electronic equipment, said outlet channel has an adjustable closing element that is adapted to let out a portion of the heated air to open air, at least a portion of the heated air that is not let out of the outlet channel from the outlet zone is returned to the inlet zone of the electronic equipment where said heated air is mixed with cold air from the supply channel, said outlet channel is situated above the supply channel and that the circulation, except for any fans within the electronic equipment as such, is provided by heated air expanding and creating an overpressure at the outlet zone of the electronic equipment wherein the electronic equipment is adapted to let air flow vertically through the electronic equipment.

2. The system according to claim 1, comprising a lower cold air supply channel for the receipt of cold supplied air, a floor above the cold air supply channel whereupon the electronic equipment is placed, one or more openings in the floor near the inlet zone of the electronic equipment, an outlet zone of the electronic equipment for air that has passed through the electronic equipment.

3. The system according to claim 1, comprising an air moisturizing device to increase the relative humidity of the supplied air.

4. The system according to claim 3, wherein the moisturizing device is placed in the inlet zone of the electronic equipment to supply atomised water to extinguish any fires that may start in the rack.

5. A power supply to a collection of a plurality of computer units placed next to each other compromising a high voltage power supply coupled to a transformer having a low voltage output, wherein the low voltage output is coupled to the input of a plurality of electrical accumulators, the output of said accumulators being coupled to said plurality of computers for supplying the computers with electrical low voltage power.

6. The power supply according to claim 5, wherein the output voltage of the accumulators being chosen according to the specific input voltage of the computers.

7. The power supply according to claim 6, wherein the input voltage is 12V.
